(19) United States
(12) Patent Application Publication
(10) Pub. No.: US 2007/0117410 A1
(43) Pub. Date: May 24, 2007

(54) Method for manufacturing semiconductor device using immersion lithography process

(75) Inventors: Jae Chang Jung, Seoul (KR); Seung Chan Moon, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyunggi-do (KR)

(21) Appl. No.: 11/481,162

(22) Filed: Jul. 5, 2006

(30) Foreign Application Priority Data
Nov. 21, 2005 (KR) 10-2005-0111278

(51) Int. Cl. G03C 5/00; H01L 21/31

(52) U.S. Cl. 438/780; 430/311

(57) ABSTRACT

Disclosed is a method for manufacturing a semiconductor device using an immersion lithography process comprising pretreating a wafer with water of least about 40° C. after an exposure step and before a post-exposure baking step, thereby effectively reducing water mark defects.

### BACKGROUND OF THE DISCLOSURE

1. Field of the Disclosure

This disclosure relates to a method for manufacturing a semiconductor device using an immersion lithography process. More specifically, it relates to a method for manufacturing a semiconductor device comprising pretreating a wafer after exposing and before post-exposure baking steps, thereby reducing water mark defects.

2. Description of the Related Technology

Recently, pattern sizes have become smaller in accordance with the smaller semiconductor devices. Research has been focused on developing exposers and corresponding photoresist materials to obtain these fine patterns. Although KrF (248 nm) and ArF (193 nm) have widely been used as exposure light sources, efforts to use light sources having shorter wavelengths such as F₂ (157 nm) or EUV (13 nm) and to increase numerical apertures of lenses have been made.

However, new exposers are required when the light sources become changed to have shorter wavelengths, making it ineffective in terms of the manufacturing cost. Also, although the increase of numerical apertures can result in the increase of resolution power, it will decrease the size of the depth of focus.

Recently, an immersion lithography process has been developing in order to solve these problems. While a dry exposure process utilizes air having a refractive index of 1.0 as a medium for exposure beams between an exposure lens and a wafer having a photoresist film, the immersion lithography process utilizes water or an organic solvent having a refractive index of more than 1.0. This enables the immersion lithography process to obtain the same effect as when a light source of a shorter wavelength is used, or as when a lens having a higher numerical aperture is used, without decrease of depth of focus.

The immersion lithography process improves the depth of focus remarkably, and enables the formation of a finer pattern even when the exposure light source of the same wavelength is used.

However, the immersion lithography process has the problem of generating water mark defects, such as that as shown in FIG. 1, in the course of the process. As a result, it is difficult to apply the immersion lithography process to the actual industrial process.

### SUMMARY OF THE DISCLOSURE

Disclosed herein is a method for manufacturing a semiconductor device which reduces water mark defects generated from an immersion lithography process.

### BRIEF DESCRIPTION OF THE DRAWINGS

For more complete understanding of the invention, reference should be made to the following detailed description and accompanying drawings wherein:

FIG. 1 is a scanning electron micrograph (SEM) showing a water mark defect generated from a conventional immersion lithography process.

The specification, drawings and examples are intended to be illustrative, and are not intended to limit this disclosure to the specific embodiments described herein.

### DETAILED DESCRIPTION

Provided herein is a method for manufacturing a semiconductor device using an immersion lithography process comprising pretreating a wafer with water of at least about 40° C. after exposing and before post-exposure baking steps. In preferred embodiments, the water can be over 40° C., at least about 50° C., over 50° C., or at least about 60° C., for example.

Specifically, a method for manufacturing a semiconductor device can comprise the steps of:

(a) forming a photoresist film over an underlying layer on a substrate;

(b) exposing the substrate using an exposer for immersion lithography;

(c) treating the substrate with water of at least about 40° C.;

(d) drying the substrate;

(e) baking the resulting substrate; and

(f) developing the resulting substrate to obtain a photoresist pattern.

Preferably, distilled water is used. The temperature of distilled water can range from about 40° C. to about 100° C., more preferably, from about 50° C. to about 90° C.

The pattern can include one or both of a line/space pattern and a hole pattern, for example.

The disclosed method is described in detail by referring to specific examples below, which are not intended to limit the invention.

In the examples, 1400i produced by ASML company was used for an exposer for immersion lithography, and water mark defects were observed by a Stells defect measuring device produced by KLA company. The results were shown by a total number of the water mark defects in the 8 inch wafer.

### COMPARATIVE EXAMPLE 1

### Pattern Formation by a Conventional Method (1)

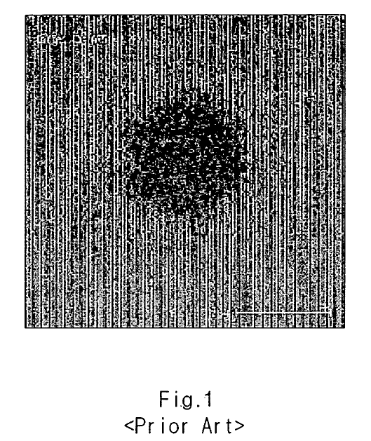

A bottom anti-reflection composition (A25 BARC produced by Dongjin Semichem Co.) was coated over a wafer, and ArF photoresist (X121 produced by Shinetsu Co.) was coated thereon to a thickness of 0.17 μm. The wafer was soft-baked at 130° C. for 90 seconds. After exposing the wafer by an immersion lithography process, the wafer was rotated at 5,000 rpm for about 2 minutes to remove water, an immersion solution. Next, the resulting wafer was post-baked at 130° C. for 90 seconds. After developing it in 2.38 wt. % TMAH aqueous solution, about 2,000 water mark defects as shown in FIG. 1 were observed.

### COMPARATIVE EXAMPLE 2

### Pattern Formation by a Conventional Method (2)

A bottom anti-reflection composition (A25 BARC produced by Dongjin Semichem Co.) was coated over a wafer, and ArF photoresist (X121 produced by Shinetsu Co.) was coated thereon to a thickness of 0.17 μm. The wafer was soft-baked at 130° C. for 90 seconds. A top anti-reflection composition (ARC 20 produced by Nitsan Chemistry Co.) was coated over the photoresist film, and then baked at 90° C. for 60 seconds. After exposing the wafer by an immersion lithography process, the wafer was rotated at 5,000 rpm for about 2 minutes to remove water. Next, the resulting wafer was post-baked at 130° C. for 90 seconds. After developing it in 2.38 wt. % TMAH aqueous solution, about 140 water mark defects as shown in FIG. 1 were observed.

The water mark defects observed in Comparative Examples 1 and 2 were presumed to be circular bridges generated in a region where water remains, because the temperature of the region was not raised in the baking step after exposure due to the high specific heat of water.

### EXAMPLE 1

### Pattern Formation by a Present Method (1)

A bottom anti-reflection composition (A25 BARC produced by Dongjin Semichem Co.) was coated over a wafer, and ArF photoresist (X121 produced by Shinetsu Co.) was coated thereon to a thickness of 0.17 μm. The wafer was soft-baked at 130° C. for 90 seconds. After exposing the wafer by an immersion lithography process, distilled water of 40° C. temperature was dropped onto the wafer for about 1 minute while the wafer was being rotated at 200 rpm. The wafer was then rotated at 5000 rpm for about 2 minutes to remove water. Next, the resulting wafer was post-baked at 130° C. for 90 seconds. After developing it in 2.38 wt. % TMAH aqueous solution, a photoresist pattern was obtained. Table 1 shows the number of resulting water mark defects.

### EXAMPLE 2

### Pattern Formation by a Present Method (2)

The procedure of Example 1 was repeated using distilled water of 50° C. instead of distilled water of 40° C., and thereby obtaining a pattern. Table 1 shows the number of resulting water mark defects.

### EXAMPLE 3

### Pattern Formation by a Present Method (3)

The procedure of Example 1 was repeated using distilled water of 60° C. instead of distilled water of 40° C., and thereby obtaining a pattern. Table 1 shows the number of resulting water mark defects.

### EXAMPLE 4

### Pattern Formation by a Present Method (4)

The procedure of Example 1 was repeated using distilled water of 70° C. instead of distilled water of 40° C., and thereby obtaining a pattern. Table 1 shows the number of resulting water mark defects.

### EXAMPLE 5

### Pattern Formation by a Present Method (5)

The procedure of Example 1 was repeated using distilled water of 80° C. instead of distilled water of 40° C., and thereby obtaining a pattern. Table 1 shows the number of resulting water mark defects.

### EXAMPLE 6

### Pattern Formation by a Present Method (6)

The procedure of Example 1 was repeated using distilled water of 90° C. instead of distilled water of 40° C., and thereby obtaining a pattern. Table 1 shows the number of resulting water mark defects.

### EXAMPLE 7

### Pattern Formation by a Present Method (7)

A bottom anti-reflection composition (A25 BARC produced by Dongjin Semichem Co.) was coated over a wafer, and ArF photoresist (X121 produced by Shinetsu Co.) was coated thereon to a thickness of 0.17 μm. The wafer was soft-baked at 130° C. for 90 seconds. A top anti-reflection composition (ARC 20 produced by Nitsan Chemistry Co.) was coated over the photoresist film, and then baked at 90° C. for 60 seconds. After exposing the wafer by an immersion lithography process, distilled water of 40° C. temperature was dropped onto the wafer for about 1 minute while the wafer was being rotated at 200 rpm. The wafer was then rotated at 5,000 rpm for about 2 minutes to remove water. Next, the resulting wafer was post-baked at 130° C. for 90 seconds. After developing it in 2.38 wt. % TMAH aqueous solution, a photoresist pattern was obtained. Table 1 shows the number of resulting water mark defects.

### EXAMPLE 8

### Pattern Formation by a Present Method (8)

The procedure of Example 7 was repeated using distilled water of 50° C. instead of distilled water of 40° C., and thereby obtaining a pattern. Table 1 shows the number of resulting water mark defects.

### EXAMPLE 9

### Pattern Formation by a Present Method (9)

The procedure of Example 7 was repeated using distilled water of 60° C. instead of distilled water of 40° C., and thereby obtaining a pattern. Table 1 shows the number of resulting water mark defects.

### EXAMPLE 10

### Pattern Formation by a Present Method (10)

The procedure of Example 7 was repeated using distilled water of 70° C. instead of distilled water of 40° C., and thereby obtaining a pattern. Table 1 shows the number of resulting water mark defects.

### EXAMPLE 11

### Pattern Formation by a Present Method (11)

The procedure of Example 7 was repeated using distilled water of 80° C. instead of distilled water of 40° C., and thereby obtaining a pattern. Table 1 shows the number of resulting water mark defects.

### EXAMPLE 12

### Pattern Formation by a Present Method (12)

The procedure of Example 7 was repeated using distilled water of 90° C. instead of distilled water of 40° C., and thereby obtaining a pattern. Table 1 shows the number of resulting water mark defects.

TABLE 1

| | Example | | | | | | | | | | | |
|---|---|---|---|---|---|---|---|---|---|---|---|---|
| | 1 | 2 | 3 | 4 | 5 | 6 | 7 | 8 | 9 | 10 | 11 | 12 |
| Number | 1254 | 42 | 0 | 0 | 0 | 0 | 121 | 12 | 0 | 0 | 0 | 0 |
| of water | | | | | | | | | | | | |
| mark | | | | | | | | | | | | |
| defects | | | | | | | | | | | | |

As shown in Table 1, water mark defects were remarkably reduced when the wafer was pretreated with hot distilled water before the baking step. Especially, no water mark defects were observed when the wafer was treated with distilled water of 60° C. and greater.

As described above, a disclosed method for manufacturing a semiconductor device includes treating a wafer with distilled water of at least 40° C. after exposing the wafer using an immersion lithography process and before baking the wafer, thereby reducing water mark defects remarkably.

What is claimed is:

1. A method for manufacturing a semiconductor device using an immersion lithography process comprising an exposure step and a post-exposure baking step, the improvement comprising pretreating a wafer with water of at least about 40° C. after an exposure step and before a post-exposure baking step.

2. The method according to claim 1, wherein the temperature of the water is over 40° C.

3. The method according to claim 2, wherein the temperature of the water is in a range of about 50° C. to about 90° C.

4. The method according to claim 1, wherein said water is distilled water.

5. A method for manufacturing a semiconductor device comprising the steps of:
(a) forming a photoresist film over an underlying layer on a substrate;
(b) exposing the substrate using an exposer for immersion lithography;
(c) treating the substrate with water of at least about 40° C.;
(d) drying the substrate;
(e) baking the resulting substrate; and
(f) developing the resulting substrate to obtain a photoresist pattern.

6. The method according to claim 5, wherein the temperature of the water is over 40° C.

7. The method according to claim 6, wherein the temperature of the water is in a range of about 50° C. to about 90° C.

8. The method according to claim 5, wherein said water is distilled water.

9. The method according to claim 5, wherein the photoresist pattern comprises one or both of a line/space pattern and a hole pattern.
